(19) United States
(12) Patent Application Publication
(10) Pub. No.: US 2020/0183511 A1
(43) Pub. Date: Jun. 11, 2020

(54) TRIBOELECTRIC SENSOR

(71) Applicant: SABIC Global Technologies B.V., Bergen op Zoom (NL)

(72) Inventors: Jesus Alfonso Caraveo FRESCAS, Thuwal (SA); Abdulaziz Hamad M. ALDUBAYAN, Thuwal (SA); Pradipta K. NAYAK, Thuwal (SA); Ramzi Salem AL-MAGHATHUWI, Thuwal (SA); Fahad ALSALEM, Thuwal (SA)

(21) Appl. No.: 16/614,966

(22) PCT Filed: May 19, 2017
(86) PCT No.: PCT/IB2017/052967

§ 371 Date: Nov. 19, 2019

(51) Int. Cl. G06F 3/041; H03K 17/96; H02N 1/04

(52) U.S. Cl. CPC G06F 3/041; H02N 1/04; H03K 17/96

(57) ABSTRACT

A triboelectric-based sensor can be used to receive touch-based input from a user and control electronic devices. The triboelectric-based sensor can be constructed with a thin film layer underneath a triboelectric later. The thin film layer may include a high resistance portion and a low resistance portion. The low resistance portion can be used to couple the triboelectric layer to the high resistance portion. The high resistance portion can have a serpentine shape and have dimensions and a sheet resistance designed to function as a thin film resistor for the triboelectric-based sensor.

### CROSS-REFERENCE TO RELATED APPLICATIONS

None.

### FIELD OF THE DISCLOSURE

The instant disclosure relates to user input devices. More specifically, this disclosure relates to user input devices based on triboelectric sensors.

### BACKGROUND

Electronic devices, particularly consumer electronics, must interact with users of the devices by means for receiving input from the user and means for providing output to the user. Classical forms of input include keyboard and mouse devices, but also include newer touch screen devices. However, these traditional techniques, although well suited for particular applications, leave much to be desired in low-cost, low power, and/or small-size form factors. That is, keyboards and mice are fairly large devices that occupy a large amount of space. In return, they offer the ability to handle fairly complex inputs. Touch screen devices consume a large amount of power, but in return can display large amounts of information or display intricate screens. Simpler devices, such as a simple switch used for light switches or power buttons, offer low cost and small size, but can generally only receive very simple input from a user, such as an on/off command.

### SUMMARY

To better interact with humans, the next generation of electronic devices can use triboelectric sensors to interact with a human's sense of the touch. A triboelectric sensor may determine an amount of force applied to the sensor by a user, such as with their hand or fingers, and translate the applied force to an electrical signal. Triboelectric-based sensors, which operate under the principle of contact electrification to detect force or touch, use a load connected to the current collector or other electrode. The load can be provided by connecting a rigid resistive element to the sensor. A rigid resistor does not allow the triboelectric sensor to have a mechanically flexible form factor, or be manufactured in a film-like configuration for mobile applications.

A thin film resistor can be used as a load to operate triboelectric sensors. Alloys of chromium-silicon (Cr—Si), nickel-chromium (Ni—Cr), and tantalum nitride (TaN) are the typical materials that may be used for the fabrication of thin film resistors for triboelectric sensors. Higher resistivity values can be achieved with other materials. Higher resistivity materials improve operation of the triboelectric sensor. A thin film resistor of 100-200 MOhms or higher as a load can provide improved operation of the triboelectric sensor. A size, or length, of the thin film resistor can be adjusted to provide a desired resistance value for a triboelectric sensor. For some configurations of material (e.g., NiCr) having low resistance values the length of the thin film resistor may be a large distance. The length of the thin film resistor can be decreased by using materials with higher resistance values. The thin film resistor can be integrated with the triboelectric sensor on a flexible substrate in a flexible sensor package.

The thin film resistor can have a shape designed to obtain a resistance value while using limited area in an integrated circuit. For example, a serpentine shape can allow longer, and thus higher resistance, thin film resistors for a triboelectric-based sensor. The thin film resistor can be coupled to a triboelectric material through an electrode. The electrode and the thin film resistor can be in the same thin film layer of the integrated circuit. Furthermore, the electrode and the thin film resistor can be made of the same material, which can be a transparent conductive oxide. The percentage of oxygen between the electrode and the thin film resistor can be adjusted to obtain a higher resistance in the thin film resistor, even when the thin film resistor and electrodes are made from the same material.

An electronic device for receiving touch-based user input can include a triboelectric sensor made with a triboelectric material and a thin film layer coupled to the triboelectric material and configured to provide a load to the triboelectric material. The thin film material can include an electrode portion coupled to the triboelectric material and a resistive portion coupled to the electrode portion. The resistive portion can be characterized by a higher resistivity than the electrode portion. In some configurations of such an electronic device, the resistive portion and the electrode portion can be made of a common material. When a transparent device is made with the triboelectric sensor, the common material can be a transparent conducting oxide, with a portion of the transparent conducting oxide treated to increase the resistance value.

One non-limiting example of an electronic device with a triboelectric sensor can be a light switch for a room. A conventional light switch must be wired to the lighting fixture between the lighting fixture and an external power supply. In a large room where a light is on opposite side of the room from the wall switch, a large amount of wire is used to connect the switch to the lighting fixture. The wire often has to pass through wall space or ceiling space that is difficult to access and/or may be damaged during the installation and require time and materials to repair. An electronic device with a triboelectric sensor can be used as a wall switch for a lighting fixture without wiring the switch to the fixture. When a user applies force to the triboelectric-based wall switch, a lighting fixture can be turned on, turned off, set to a desired brightness, and/or set to a desired color.

Although a wall switch is described as one application for embodiments of the invention described herein, other applications are possible. For example, an electronic device with a triboelectric sensor can be incorporated into consumer electronic devices, such as mobile devices, as power switches, as volume controls, or as another input device. When the materials for the triboelectric-based sensor are transparent, the triboelectric-based sensor can be integrated into a display device. Furthermore, although a lighting fixture is described as a receiver of remote communications, the force sensitive device can communicate a touch event to any device communicatively coupled to light bulbs or any other processing unit such as an automation system, light management system, personal computer, or a mobile device that is able to interrogate another electronic device. The applications are not limited to light switches, but can be used as a substitute or supplement to any mechanical switching system. These switches may not require wiring to the central unit and the installation is simpler. For example, the mechanical switches in vehicles (e.g., engine start, doors, windows, seats, and the like) can be controlled wirelessly according to embodiments of invention.

An electronic device can be manufactured, such as through an exemplary method that includes forming a triboelectric-based sensor on a substrate; forming an integrated circuit, such as a communications device and/or read-out circuitry, on the substrate; and/or coupling the IC to the triboelectric-based sensor through a thin film resistor. The triboelectric-based sensor can be manufactured with an electrode portion of a thin film layer underneath the triboelectric material, that electrode portion may be coupled to a resistive portion functioning as the thin film resistor for the triboelectric sensor.

The triboelectric thin film layer can include at least one of a perfluoronated copolymer, polyvinylidene fluoride (PVDF), a copolymer of PVDF, polydimethylsiloxane (PDMS), poly(methylmethacrylate) (PMMA), polytetrafluoroethylene (e.g., Teflon® (Chemours Co., U.S.A.)), poly-xylylene polymer (e.g., parylene polymers), polymer foam, poly(methylmethacrylate)-co-poly(1H-1H-perfluorooctyl methacrylate), a fluorinated polymer, an electronegative polymer, or other polymers, or blends thereof. The triboelectric-based sensor and other parts, or all of, the triboelectric-based sensor may be flexible. For example, the sensor or apparatus can be formed on at least one of polyethylene terephthalate (PET), polyethylene naphthalate (PEN), polycarbonate (PC) or co-polymers thereof, PMMA, polyimide, and/or another thermoplastic material or blends thereof. In some embodiments, the substrate may also be transparent.

The triboelectric-based sensor can facilitate the processing and transmission of user input received at the triboelectric-based sensor. A processor, or other logic circuitry, can be configured through hardware, software, and/or firmware to execute steps including receiving, at a triboelectric-based sensor of a touch device, an applied force; and converting, at the triboelectric-based sensor of the touch device, the applied force to an electrical signal that causes the electronic device to perform certain other processing steps, such as transmission of the user input to another electronic device, power on/off the electronic device, increase or decrease a volume of the electronic device, and/or the like.

The following includes definitions of various terms and phrases used throughout this specification.

“Triboelectric sensor” or “triboelectric-based sensor” refer to an electronic component configured to generate control signals from user input to a triboelectric material. The triboelectric sensor is an electronic component that may be integrated with or coupled to an electronic device such as a cellular phone, mobile phone, laptop computer, among others.

The terms “about” or “approximately” are defined as being close to as understood by one of ordinary skill in the art. In one non-limiting embodiment, the terms are defined to be within 10%, preferably within 5%, more preferably within 1%, and most preferably within 0.5%.

The term “substantially” and its variations are defined to include ranges within 10%, within 5%, within 1%, or within 0.5%.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims, or the specification, may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The apparatus of the present invention can “comprise,” “consist essentially of,” or “consist of” particular ingredients, components, compositions, etc. disclosed throughout the specification. With respect to the transitional phase “consisting essentially of,” in one non-limiting aspect, a basic and novel characteristic of the apparatus of the present invention are their abilities to facilitate the processing and transmission of user input.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

For a more complete understanding of the disclosed system and methods, reference is now made to the following descriptions taken in conjunction with the accompanying drawings.

FIG. 1 is a top-down view of a triboelectric-based sensor with a thin film load resistor according to some embodiments of the disclosure.

FIG. 2 is a flow chart illustrating a method of forming a triboelectric-based sensor with a thin film load resistor according to some embodiments of the disclosure.

FIG. 3 is a cross-sectional view of a triboelectric-based sensor with a thin film load resistor according to some embodiments of the disclosure.

FIG. 4 is a top-down view of a triboelectric-based sensor with a thin film load resistor with a serpentine shape according to some embodiments of the disclosure.

FIG. 5 is a flow chart illustrating a method of forming a triboelectric-based sensor with a thin film load resistor using patterned deposition according to some embodiments of the disclosure.

FIG. 6 is a graph illustrating a sheet resistance of a transparent conductive material as a function of oxygen partial pressure in the material according to some embodiments of the disclosure.

FIG. 7 is a graph illustrating an output of a triboelectric-based sensor using PVDF-TrFE with a 200 MegaOhm thin film load resistor according to some embodiments of the disclosure.

FIG. 8 is a flow chart illustrating a method of forming a triboelectric-based sensor with a thin film load resistor by modifying a deposited thin film according to some embodiments of the disclosure.

FIG. 9 is a cross-sectional view of a triboelectric-based sensor with a thin film load resistor and a protection film according to some embodiments of the disclosure.

FIG. 10 is a block diagram illustrating a method of operation of a triboelectric-based sensor according to some embodiments of the disclosure.

FIG. 11 is a block diagram illustrating an integrated circuit for processing signals from a triboelectric-based touch sensor according to some embodiments of the disclosure.

FIG. 12 is a flow chart illustrating an exemplary method for using a triboelectric-based sensor for generating wireless control signals according to some embodiments of the disclosure.

FIG. 13 is a block diagram illustrating an apparatus with an array of triboelectric-based touch sensors according to some embodiments of the disclosure.

FIG. 14 is an illustration of a room with a triboelectric-based light switch according to some embodiments of the disclosure.

FIG. 15 is an illustration of a room with a triboelectric-based light switch with an array of triboelectric-based force sensors according to some embodiments of the disclosure.

### DETAILED DESCRIPTION

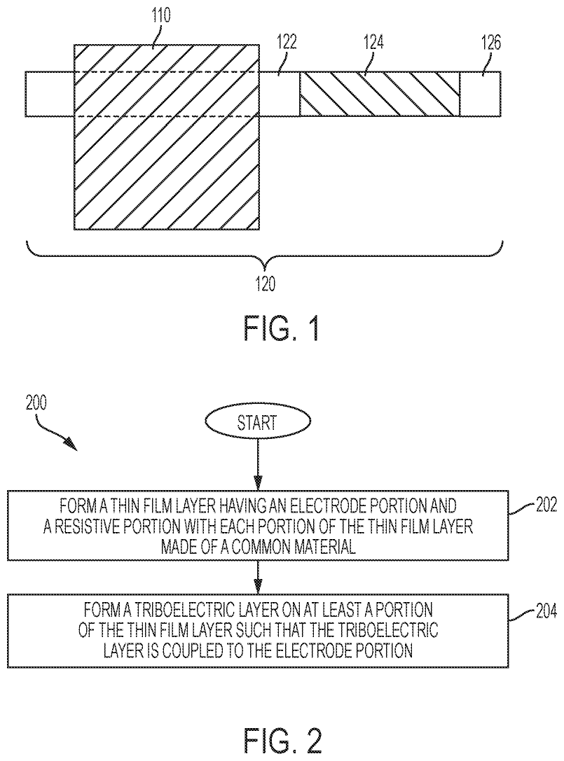

FIG. 1 is a top-down view of a triboelectric-based sensor with a thin film load resistor according to some embodiments of the disclosure. A triboelectric material 110 may be deposited as a triboelectric layer or second layer on a first thin film layer 120. The thin film layer 120 may include a first electrode portion 122 in contact with the triboelectric material 110, a resistive portion 124, and a second electrode portion 126. An apparatus built around the triboelectric-based sensor 100 may include a force sensor, an integrated circuit (IC), and/or other components, such as a radio frequency (RF) antenna. The triboelectric material 110 may include PVDF or its copolymers (e.g., PVDF-trifluoroethylene (TrFE), PVDF-TrFE chlorofluoroethylene (CFE), and PVDF-hexafluoropropylene (HFP)), PDMS, PMMA, polytetrafluorethylene (e.g., Teflon®), polymer foams, poly(methylmethacrylate)-co-poly(1H-1H-perfluorooctyl methacrylate), or other electronegative polymers. The thin film layer 120 may be made from one or more of tantalum nitride, silicon chromium alloys nickel chromium alloys, and/or transparent conductive materials (e.g., indium tin oxide (ITO)). A method of fabricating a triboelectric-based sensor with thin film resistor is described with reference to FIG. 2.

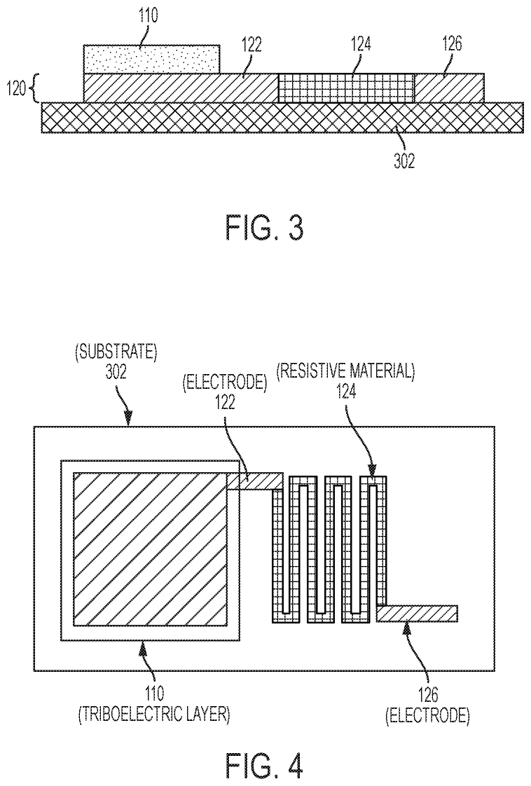

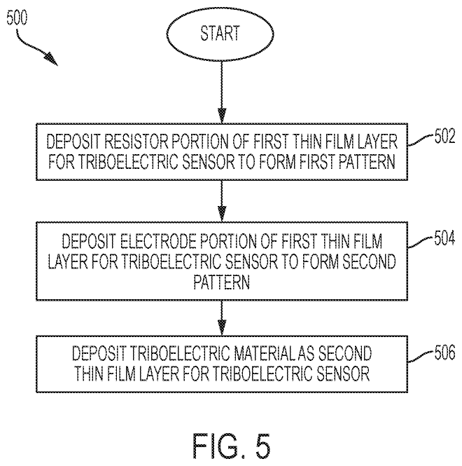

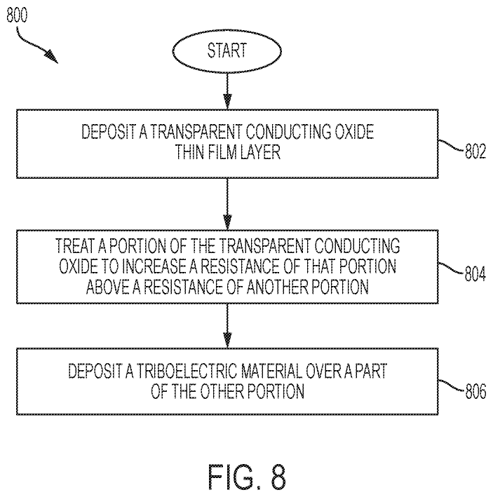

FIG. 2 is a flow chart illustrating a method of forming a triboelectric-based sensor with a thin film load resistor according to some embodiments of the disclosure. A method 200 begins at block 202 with forming a thin film layer having an electrode portion and a resistive portion. In some embodiments, the electrode portion and the resistive portion can be made from a common material, such as a transparent conductive material (e.g., ITO). Some techniques for forming the thin film layer and its different portions are described in more detail below with reference to FIG. 5 and FIG. 8. Next, at block 204, a triboelectric layer may be formed on at least part of the thin film layer formed at block 202. The triboelectric layer may be coupled to the thin film layer. The coupling may be by physical contact between the triboelectric material and the electrode portion of the thin film layer. A cross-sectional view of an example resulting structure fabricated according to the method 200 is shown in FIG. 3.

FIG. 3 is a cross-sectional view of a triboelectric-based sensor with a thin film load resistor according to some embodiments of the disclosure. A thin film layer 120 can be deposited on a substrate 302. The substrate 302 can be one of PET, PEN, PC, PMMA, polyimide, or other thermoplastic materials, or flexible or inflexible substrate materials. Some layers may be present between the substrate 302 and the thin film layer 120, such as precursor layers and/or circuitry layers. The thin film layer 120 may include the first electrode portion 122, the resistive portion 124, and the second electrode portion 126. The triboelectric material 110 is shown above the first electrode portion 122 and in contact with the first electrode portion 122. Electrical contact with the triboelectric material 110 can be made by external circuitry through the second electrode 126, through the resistive portion 124, and the first electrode portion 122. A force signal proportional to force applied to the triboelectric material 110 may be measured from the triboelectric material 110 by such external circuitry through the electrode portion 126.

The resistive portion 124 can be patterned into one of many different shapes, which may be seen from a top-down view of the structure. One example shape for the resistive portion 124 is a serpentine pattern. The resistance provided by the resistive portion 124 may be proportional to a length between the first electrode portion 122 and the second electrode portion 126. The serpentine pattern can provide a long length without consuming a large amount of die area. FIG. 4 is a top-down view of a triboelectric-based sensor with a thin film load resistor with a serpentine shape according to some embodiments of the disclosure. The resistive material 124 is shown in a serpentine pattern between the first electrode portion 122 and the second electrode portion 126. Other example shapes for the resistive material 124 include a straight line, a diagonal line, a chord, or other shape.

The thin film layer may be formed with different characteristics, e.g., resistances, in the resistive portion and the electrode portion. One example process for fabricating such a device is described with reference to FIG. 5. FIG. 5 is a flow chart illustrating a method of forming a triboelectric-based sensor with a thin film load resistor using patterned deposition according to some embodiments of the disclosure. A method 500 may begin at block 502 with depositing a resistor portion of a first thin film layer to form a first pattern. Some of the first pattern may include serpentine shapes. Then, at block 504, an electrode portion of the first thin film layer can be deposited to form a second pattern. The second pattern can be aligned with the first pattern such that the electrode portion contacts the resistor portion at certain locations. Those locations may place the resistor portion of the second pattern in contact on two ends with a first and second electrode from the electrode portion. Then, at block 506, a triboelectric material may be deposited as a second thin film layer on the first thin film layer. The triboelectric material can have a third pattern. The third pattern can be aligned such that the triboelectric material may overlap or otherwise form electrical contact with an electrode in the electrode portion of block 504.

The formation of the first pattern of block 502 and the second pattern of block 504 can be performed by one or more semiconductor fabrication techniques. For example, lift-off patterning can be formed by depositing a photoresist layer, patterning the photoresist layer with the first pattern, developing the photoresist layer, depositing a material for the resistor portion, and then lifting off the remaining photoresist layer. Either positive-tone or negative-tone photoresist materials may be used and the patterning adjusted accordingly to obtain the desired first pattern. In some embodiments, another temporary layer can be used in addition to the photoresist layer. As another example, a resistive material for the resistor portion may be deposited, a photoresist layer deposited on the resistive material, the photoresist layer patterned with the first pattern, the first pattern transferred from the photoresist layer to the resistive material, and then the photoresist layer removed. As a further example, the resistive and electrode portions may be printed as an alternative fabrication process. Similar processing methods may be used for the formation of the electrode portion of the second pattern at block 504 and the triboelectric material at block 506.

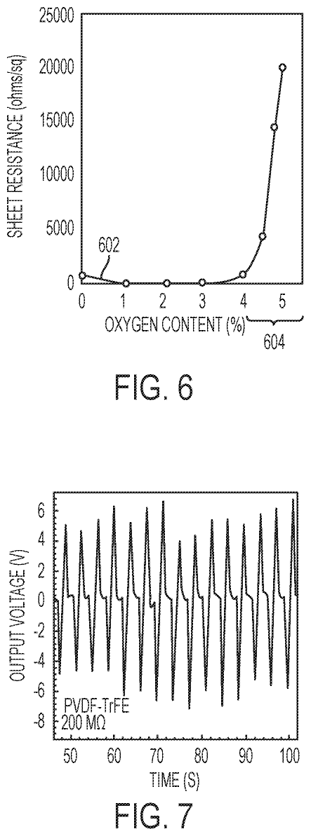

The resistor portion and the electrode portion of the first thin film layer may be the same or different materials. For example, for a transparent device the resistor and electrode portions may both be a transparent conductive material (e.g., ITO). The deposition process for the transparent conductive material may be altered to change a resistivity of the transparent conductive material to be higher for the resistor portion and lower for the electrode portion. Deposition processes can be adjusted to change the resistivity by, for example, adding oxygen to the material during deposition, changing energies during plasma deposition, changing chemistry during vapor deposition, or the like. In some embodiments, the resistor portion and electrode portion may be different materials. One non-limiting example of a technique for adjusting resistivity of a material to allow the same material to be used for electrode and resistor portions is described with reference to FIG. 6.

FIG. 6 is a graph illustrating a sheet resistance of a transparent conductive material as a function of oxygen partial pressure in the material according to some embodiments of the disclosure. A line 602 shows a sheet resistance of ITO, a transparent conductive material, as a function of oxygen partial pressure during deposition. The sheet resistance is relatively low for low oxygen partial pressure, but increases rapidly beyond a threshold oxygen partial pressure in region 604. For some materials, the sheet resistance may increase significantly beyond approximately 3 to 4% oxygen partial pressure. In an embodiment of the ITO material shown in FIG. 6, the resistor portion of the first thin film layer of block 502 may be ITO deposited with oxygen partial pressure above 4% and the electrode portion of the first thin film layer of block 504 may be ITO deposited with oxygen partial pressure below 4%. Higher oxygen partial pressure during deposition of the material results in more oxygen incorporation into the ITO film, which modifies the characteristics of the ITO film such as by increasing resistance of the ITO film. A similar technique of oxygen incorporation, or incorporation of other elements or materials, into other conductive materials can be used to modify other conductive materials to form a resistive portion in a similar manner.

A triboelectric-based sensor similar to that illustrated in FIG. 3 and FIG. 4 was tested to demonstrate operation of the sensor. The sensor was manufactured according to a process similar to that of FIG. 5 with ITO for resistor and electrode portions of the sensor with properties similar to those illustrated in FIG. 6. The output of the sensor is shown in FIG. 7. FIG. 7 is a graph illustrating an output of a triboelectric-based sensor using PVDF-TrFE with a 200 MegaOhm thin film load resistor according to some embodiments of the disclosure. The sensor includes a PVDF-based triboelectric material for the second thin film layer, and ITO transparent conductive material for the first thin film layer. The resistor portion is shaped in a serpentine manner to obtain a 200 MegaOhm thin film resistor coupled to the triboelectric material. An output of the sensor is shown in the graph of FIG. 7. A repeated application and release of force to the triboelectric material causes the output signal from the sensor, read from an electrode of the electrode portion of the first thin film layer, to increase and decrease. The peak-to-peak output signal may be up to 10 Volts, which is easily detected with an integrated circuit coupled to the triboelectric-based sensor. The output signal can be adjusted by adjusting the resistance value of the thin film resistor coupled to the triboelectric-based sensor.

The manufacturing process described in FIG. 5 and tested with the test sensor of FIG. 7 is only one process for manufacturing a triboelectric-based sensor in accordance with aspects of this disclosure. Another manufacturing process is described in FIG. 8. Whereas FIG. 5 describes separate patterning of two portions of the first thin film layer, a single deposition step may be used to form the separate portions of the first thin film layer. A portion of the deposited material may then be treated after deposition to form resistive and electrode portions, either by treating portions to increase conductivity or treating portions to increase resistivity. FIG. 8 is a flow chart illustrating a method of forming a triboelectric-based sensor with a thin film load resistor by modifying a deposited thin film according to some embodiments of the disclosure.

A method 800 may begin at block 802 with depositing a material, such as a transparent conducting material (e.g., ITO) thin film layer. The deposited film may have characteristics desirable for the electrode portion of the first thin film layer. A portion of the first thin film layer may be treated at block 804 to increase a resistance of that portion above a resistance of the original film deposited at block 802. For example, a photoresist layer can be deposited on the ITO and patterned and developed according to the first pattern to expose a portion of the ITO. Then, the exposed portion of the ITO may be bombarded with oxygen ions to increase the oxygen content of the ITO film, or otherwise modify the structure of the ITO to increase resistivity. The photoresist layer and other temporary layers may be removed. A triboelectric material may then be deposited at block 806. The deposited triboelectric material may make electrical contact over a portion of the thin film layer not modified by the treatment of block 804.

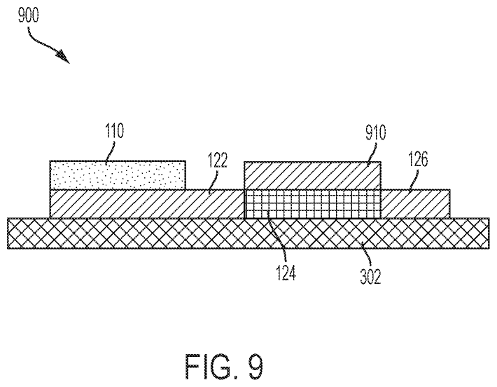

A protective layer may be used to protect the resistive portion of the thin film layer from unintended modifications or damage. FIG. 9 is a cross-sectional view of a triboelectric-based sensor with a thin film load resistor and a protection film according to some embodiments of the disclosure. The resistors may be coated by an appropriate oxygen barrier material, such as to protect from oxidization that may affect the resistivity of film. The protection layer material may be the same material as the active material of the touch sensor, e.g., PVDF-based materials, or another suitable oxygen and moisture barrier material. An example embodiment using a protective layer is illustrated as sensor 900. A protective material 910 may be deposited and/or patterned over resistive portion 124. The protective material 910 may overlap over portions of the electrode portions 122 and 126 to seal the resistive portion 124 from external conditions. The protective material 910 may have a shape that matches the resistive portion 124, such as a serpentine shape. Alternatively, the protective material 910 may have a shape that covers the resistive portion 124, such as a rectangular shape that spans the serpentine shape of the resistive portion 124. In some embodiments, the protective material 910 may be deposited simultaneously with triboelectric material 110 during, for example block 204 of the manufacturing process of FIG. 2.

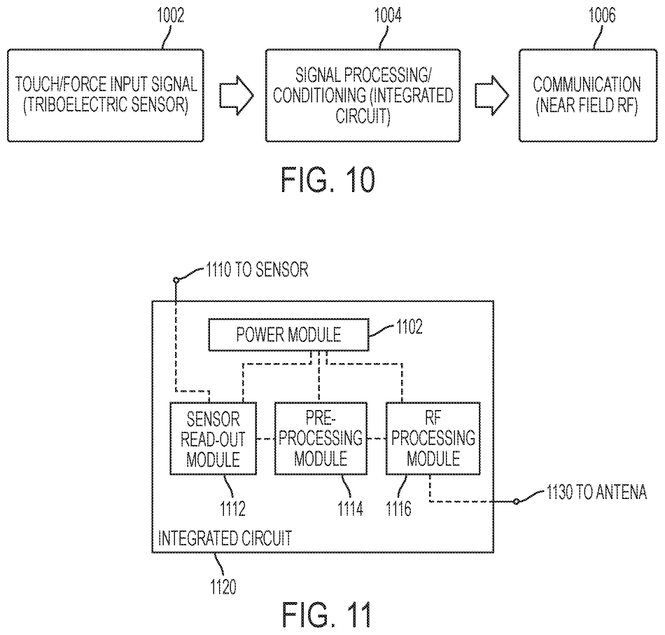

Exemplary operation of a triboelectric-based sensor, such as by the apparatus of FIG. 1, is described in more detail with reference to FIG. 10. FIG. 10 is a block diagram illustrating a method of operation of a triboelectric-based sensor according to some embodiments of the disclosure. Dataflow for operation of a triboelectric-based sensor may begin at block 1002 with an integrated circuit receiving a force input signal from the triboelectric-based force sensor. Then, at block 1004, the integrated circuit may perform signal processing, which may include signal conditioning, and/or other mathematical determinations or logic decisions based on the received input from the force sensor of block 1002. The processed sensor signal may be used internal to an electronic device incorporating the force sensor. The processed signal may be used to control operation of the electronic device, such as by indicating user input to the device to change operating conditions or power on/off the device. In some embodiments, the processed signal may be transmitted to another information system and used to affect operation of another information system or used to generate a control command for affecting operation internal of the electronic device. At block 1006, the integrated circuit may communicate wirelessly with another device, such as by transmitting a signal based, at least in part, on a signal received from a force sensor at block 1002 and processed in block 1004.

A non-limiting example circuit for reading out the force sensor is shown in FIG. 11. FIG. 11 is a block diagram illustrating an integrated circuit for processing signals from a triboelectric-based touch sensor according to some embodiments of the disclosure. An IC 1120 may be coupled to a force sensor 1110 to read out the output signal of the force sensor 1110. The force sensor 1110 may be a triboelectric-based sensor, such as described in embodiments shown in FIG. 1, FIG. 3, and FIG. 4, or other embodiments. The IC 1120 may process the output signal received from the force sensor 1110 to determine an amount of force applied to the force sensor 1110. For example, the IC 1120 may use a look-up table, an equation, an algorithm, or machine learning to translate an output signal from the force sensor 1110 to a relative or absolute force value. In some embodiments, the force value may be used to determine whether a user has touched the force sensor 1110. In some touch sensor embodiments, the IC 1120 may determine whether the force applied to the force sensor 1110 exceeds a threshold amount that would indicate a deliberate touch on the force sensor 1110. This binary determination may be used, for example, to turn on or off devices. The IC 1120 may include electrodes, interconnects, and/or antennas made from one or more of aluminum, copper, silver, indium tin oxide (ITO), aluminum-doped zinc oxide (AZO), poly(3,4-ethylenedioxythiophene) polystyrene sulfonate (PEDOT:PSS), or any other conductive material, or blends thereof.

The IC 1120 may transmit the determined applied force, or other values derived from the applied force, through an antenna 1130. For example, a scaled analog value between 0 and 100 may be generated by the IC 1120 based on the output signal of the force sensor 1110, and that scaled analog value transmitted through the antenna 1130. In another example, a binary value of true or false may be generated by the IC 1120 based on the output signal of the force sensor 1110 being higher or lower than a threshold value, and that binary value transmitted through the antenna 1130. The IC 1120 may communicate using the antenna using any wireless communications technique. In some embodiments, the IC 1120 may include Bluetooth® (Bluetooth Special Interest Group, U.S.A.) functionality and operate the antenna according to the Bluetooth® standard. In some embodiments, the IC 1120 may include WiFi functionality and operate the antenna in accordance with the IEEE 802.11 standard. In some embodiments, the IC 1120 may include frequency modulation (FM) or amplitude modulation (AM) circuitry to transmit signals through the antenna.

One specific IC 1120 configured to provide some of the above-described functionality is shown in FIG. 11. The IC 1120 may include an input node for receiving signals from the sensor 1110, such as when coupled to an electrode portion of the first thin film layer. The received signal may be received by a sensor read-out module 1112. The read-out may be provided to pre-processing module 1114, which may perform operations on and/or involving the read-out from the sensor 1110. The processed signal may be provided to an RF processing module 1116, which may perform operations to transmit data to another device, such as by generating physical signals for output to other circuitry in an electronic device, such as a network interface for output of the signals to an RF antenna 1130.

In some embodiments, the IC 1120 may include a power module 1102. The power module 1102 may receive a supply voltage from a power supply and distribute power to the modules 1112, 1114, and 1116. The power module 1102 may include circuitry such as power converters, DC-to-DC converters, charge pumps, and the like to convert the supply voltage into a steady-state DC power supply for operating the modules 1112, 1114, and 1116. For example, the power module 1102 may generate a 1.8 Volt DC power supply for operating the modules 1112, 1114, and 1116.

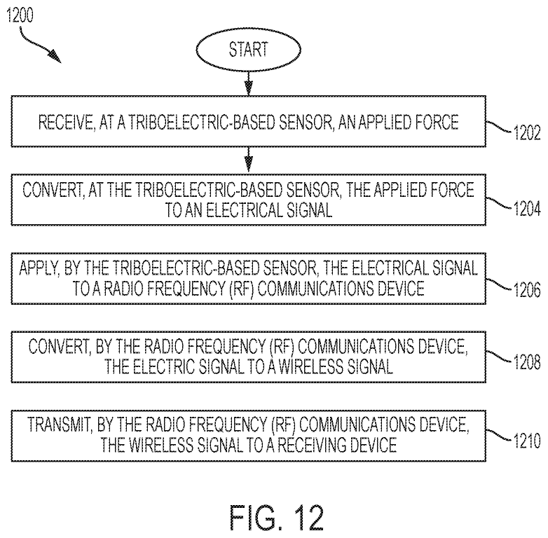

The modules 1112, 1114, and/or 1116 may include circuitry configured to perform the operations described herein. In some embodiments, such as when the IC 1120 is a general-purpose processor, the modules 1112, 1114, and/or 1116 may be software code that when executed by a general-purpose processor cause the processor to perform the operations described herein. In some embodiments, the modules 1112, 1114, and/or 1116 may include circuitry or other hardware configured to perform certain functionality. In some embodiments, the circuitry or other hardware may be configured using firmware. One example of a method for implementation by the modules 1112, 1114, and/or 1116, in cooperation with the sensor 1110, is described with reference to FIG. 12.

FIG. 12 is a flow chart illustrating an exemplary method for using a triboelectric-based sensor for generating wireless control signals according to one embodiment of the disclosure. A method 1200 may begin at block 1202 with receiving, at a triboelectric-based sensor, an applied force. At block 1204, the applied force at the triboelectric-based sensor may be converted to an electric signal. For example, a user's finger may apply a force to a triboelectric layer, which generates charges in the triboelectric layer as a result of the principle of contact electrification. The user's applied force may correspond to an input signal. For example, tapping the triboelectric material may indicate turning on or off a device, such as a lighting device and tapping the triboelectric material twice may indicate turning off or on a device. As another example, tapping the triboelectric material may indicate initiating or hanging up a telephone call or other communications session.

Charges are generated in the triboelectric layer upon contact with a material having an opposite electro affinity. For example, charges are generated when a human finger touches the triboelectric layer as a result of the principle of contact electrification (e.g., triboelectrification). The power output of the sensor may depend on the load (e.g., resistance) of the system. The resistors may be formed from the resistor portions of the first thin film layer. The signal generated by the triboelectric-based force sensor may be conveyed to a thin film integrated circuit for conditioning and pre-processing before being communicated via near field radio frequency communication to a receiving device.

Referring back to FIG. 12, at block 1206, the electrical signal from the triboelectric-based sensor may be applied to a radio frequency (RF) communications device. The RF communications device may include an integrated circuit, such as integrated circuit 1120 of FIG. 11. The integrated circuit 1120 may include, for example, a sensor read-out module 1112, configured to receive the electrical signal from the triboelectric-based sensor at block 1206. The RF communications device may then perform steps to prepare the output of the force sensor for transmission, and then transmit a signal that corresponds to the output of the force sensor. At block 1208, the electrical signal may be converted by the RF communications device to a wireless signal. In one embodiment, the conversion of block 1208 may be performed by pre-processing module 1114 and/or RF processing module 1116 of FIG. 11. For example, the electrical signal may be processed and used to generate wireless signals for near-field RF communications. At block 1210, the wireless signal may be transmitted by the RF communications device to a receiving device, such as through RF antenna. In one embodiment, the transmission of block 1210 may be performed by the RF processing module 1116 and/or the RF antenna. The receiving device may be a lighting device, such as a lamp or communication-enabled LED-based light bulb. The receiving device may alternatively be a computing device, such as a mobile phone, a tablet, a laptop computer, or a desktop computer.

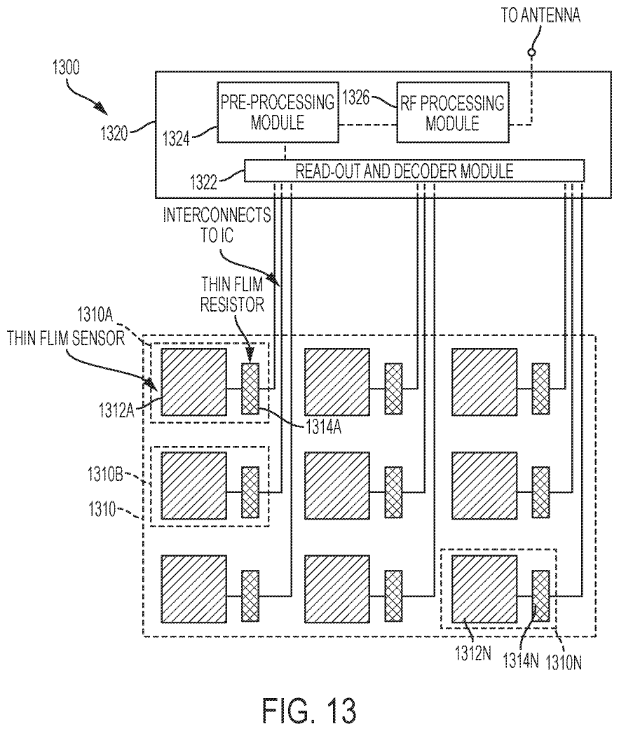

Example embodiments described above include a single triboelectric-based sensor, however, in some embodiments, multiple sensors may be organized into an array FIG. 13 is a block diagram illustrating an apparatus with an array of triboelectric-based touch sensors according to one embodiment of the disclosure. An electronic device 1300 may include an array 1310 of triboelectric-based sensors. Each of the triboelectric-based sensors 1310A-N may include a thin film sensor 1312A-N having a triboelectric active layer and a thin film resistor 1314A-N. The thin film resistors 1314A-N may be the resistor portions of the first thin film layer illustrated as material 124 in FIG. 1, FIG. 3, and FIG. 4. Each of the sensors 1310A-N of the array 1310 may be coupled to an integrated circuit (IC) 1320 for processing the signals generated by the sensors 1310A-N. The IC 1320 may include a read-out and decoder module 1322 configured to receive input signals from each of the sensors 1310A-N and decode a resulting output. For example, the module 1322 may be able to decode the signals to determine which of the sensors 1310A-N were touched. In another example, the module 1322 may be able to decode the signals to determine an input value, such as where pressure applied to different areas indicates different input values. The read-out and/or decoded data may be passed to pre-processing module 1324 to perform operations similar to the pre-processing module 1114 of FIG. 11, and then to RF processing module 1126 to perform operations similar to the RF processing module 1116 of FIG. 11.

In some embodiments, the thin film sensor array 1310 and/or IC 1320 may be built on a flexible plastic substrate allowing the device to take different form factors. For example, the device may be fabricated on a flat substrate and, after proper encapsulation, the device may be used as a remote light switch that connects with a reader unit that is connected directly to a light bulb. A device with multiple sensors may be used to control the light intensity by touching different areas of the array of sensors, which are mapped to the different intensities and may be decoded by the module 1322. In one mapping, increasing the light intensity may be indicated by a user as consecutive columns are touched. As another example, the device may be fabricated on a transparent flexible substrate and the device may have a transparent electrode portion, a transparent resistive portion, and a transparent triboelectric material, such that the device can be incorporated into a display device.

Thin film triboelectric sensors according to some embodiments may have a triboelectric layer based on a perfluoronated copolymer. The perfluoronated copolymer may be, for example, poly(methyl methacrylate)-co-poly(1H-1H-perfluorooctyl methacrylate). The perfluoronated copolymer may be manufactured by known step polymer techniques. In one non-limiting example, the copolymer can be polymerized using a free radical initiator in a nonpolar inert solvent capable of dissolving the polymer precursors (e.g., benzene). In some embodiments, the perfluoronated copolymer may have a controlling perfluoro segment in proportion by weight of more than approximately fifty percent. Particular embodiments of synthesis for a triboelectric thin film are described below, but other copolymers, such as those described above, may be manufactured by different techniques.

In one embodiment, poly(methylmethacrylate)-co-poly(1H-1H-perfluorooctyl methacrylate) can be synthesized from methylmethacrylate (1) and (1H-1H-perfluorooctyl methacrylate (2) to produce poly(methylmethacrylate)-co-poly(1H-1H-perfluorooctyl methacrylate) (3) as shown in the reaction scheme below:

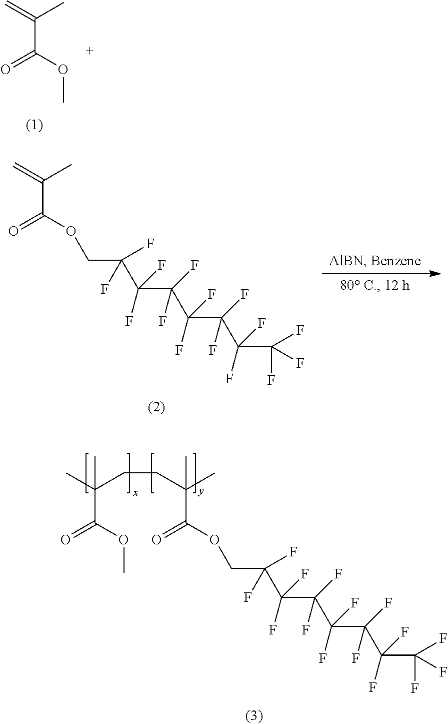

In one embodiment, the synthesis can include purification of the starting materials. By way of example, benzene can be dried and purified by refluxing benzene over sodium/potassium alloy in the presence of benzophenone until the characteristic blue color of the benzophenone radical anion was present and then distilled. Azo-bisisobutyronitrile (AIBN) can be recrystallized from methanol and dried in vacuum. Methylmethacrylate can freshly distilled under a N₂ atmosphere prior to use. 1H-1H-perfluorooctyl methacrylate can be purified by passing through a basic alumina column and dried over sodium sulfite (Na₂SO₄). Dry benzene (e.g., 30 mL) was added to a reactor equipped with a nitrogen inlet and reflux condenser in subdued light. The benzene was degassed (e.g., nitrogen gas can be passed through the benzene for about 1.5 hours), and methyl methacrylate (1) (e.g., 1.0 g (10 mmol)) and 1H-1H-perfluorooctyl methacrylate (2) (e.g., 1.0 g (2.1 mmol)) was added under agitation until dissolution of the reagents. 2,2′-Azobis-isobutyronitrile (AIBN, e.g., 20 mg) was added, and the reaction mixture was allowed to react at 75 to 85 ° C. or about 80 ° C. with agitation until the reaction was considered complete (e.g., about 10 to 15 hours or about 12 hours). The co-polymer was precipitated from the viscous solution by the addition of a polar solvent (e.g., 250 mL of methanol). The co-polymer was isolated using known solid/liquid techniques (e.g., filtration, centrifugation, and the like), and was further purified by two subsequent precipitations from chloroform into methanol. The purified copolymer was isolated and dried under vacuum. The resulting polymer had a white color. The resultant copolymer can have a molecular weight of between 5,000-50,000, or more particularly 8,700, and a dispersity index (DPI) of 1.5-2.5, or more particularly 2.01.

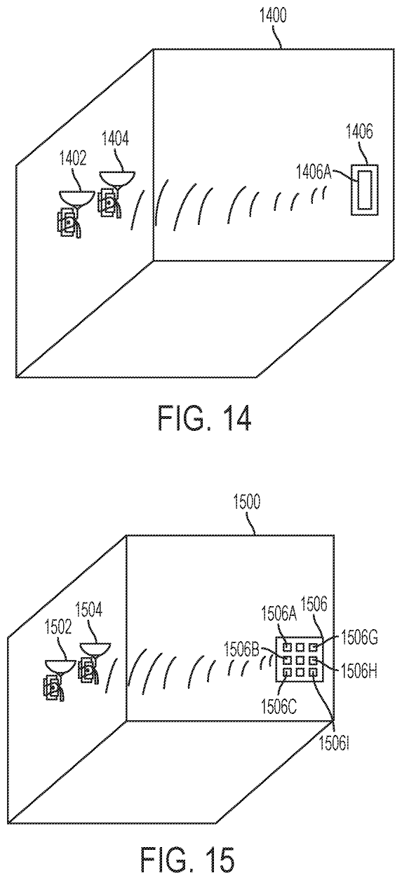

One example application for an electronic device with a triboelectric sensor is wall switches for operating lighting fixtures. FIG. 14 is an illustration of a room with a triboelectric-based light switch according to one embodiment of the disclosure. A room 1400 may include lighting fixtures 1402 and 1404. An electronic device, such as wall switch 1406, may include a triboelectric sensor 1406A. When pressure is applied to the triboelectric sensor 1406A, the sensor 1406A may generate an electrical signal that is conveyed to an RF communications device. An integrated circuit in the RF communications device may receive the signal, process the signal, and generate an RF signal for application to an RF antenna. The RF communications device may thus generate and/or cause transmission of a control signal based on an applied force to the sensor 1406A. The control signal may be transmitted to the lighting fixtures 1402 and 1404 to turn on or turn off the fixtures 1402 and 1404 or to dim the fixtures 1402 and 1404 to a level indicated by the applied force to the sensor 1406A. Although wall lighting fixtures 1402 and 1404 are illustrated in FIG. 14, the wall switch 1406 may control any device in the room, including power outlets, stereo equipment, televisions, air conditioners, heaters, mobile devices, home automation systems, etc.

An array of triboelectric sensors may be used in a wall switch for operating lighting fixtures as shown in FIG. 15. FIG. 15 is an illustration of a room with a triboelectric-based light switch with an array of triboelectric-based force sensors according to one embodiment of the disclosure. A room 1500 may include lighting fixtures 1502 and 1504 and a wall switch 1506. The switch 1506 may include triboelectric sensors 1506A-I. The switch 1506 may operate similar to the switch 1406 but transmit different signals or a plurality of signals to a plurality of devices. For example, one sensor 1506A may be used to control the lighting fixture 1502, while a second sensor 1506B may be used to control the lighting fixture 1504. In another example, the sensors 1506A-I may be used to control an intensity of each fixture 1502-1504, such as when one column of sensors 1506A-C varies the intensity of fixture 1502 and another column of sensors 1506D-F varies the intensity of fixture 1504. In a further example, the sensors 1506A-I may be used to control color of the fixtures 1502 and 1504, such as when one column of sensors 1506A-C varies an intensity of emitted red light, a second column of sensors 1506D-F varies an intensity of emitted green light, and a third column of sensors 1506G-I varies an intensity of emitted blue light from the lighting fixtures 1502 and 1504.

A triboelectric-based sensor may be improved according to certain embodiments described herein and in accordance with the principles and techniques described herein. The output voltage (or power) generated by the triboelectric-based sensor depends, in part, on the load (e.g., resistance) of the resistor coupled to the sensor. Enhancements described herein may allow integration of a thin film resistor made of transparent conducting oxide (TCO) with a triboelectric-based touch/force sensor, in which the load (or resistance value) can be adjusted by an amount of oxygen incorporated into the TCO film, such as by changing an oxygen level present during the deposition of the TCO film. Non-limiting examples of transparent conducting oxides include tin-doped indium oxide (ITO), aluminum-doped zinc oxide (AZO), gallium-doped zinc oxide (GZO), tin dioxide (SnO₂), and fluorine-dope tin oxide (FTO).

If implemented in firmware and/or software, the functions described above, such as with respect to the illustrations of FIG. 10, FIG. 11, FIG. 12, and FIG. 13, may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically erasable programmable read-only memory (EEPROM), compact-disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks, and Blu-ray discs. Generally, disks reproduce data magnetically, and discs reproduce data optically. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The described methods are generally set forth in a logical flow of steps. As such, the described order and labeled steps of representative figures are indicative of aspects of the disclosed method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagram, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1. An apparatus, comprising:
a triboelectric material; and
a thin film layer coupled to the triboelectric material, wherein the thin film layer comprises an electrode portion coupled to the triboelectric material and a resistive portion coupled to the electrode portion, wherein the resistive portion has a higher resistivity than the electrode portion, and wherein the thin film layer comprises a transparent conducting oxide.

2. The apparatus of claim 1, wherein the transparent conducting oxide comprises at least one of tin-doped indium oxide (ITO), aluminum-doped zinc oxide (AZO), gallium-doped zinc oxide (GZO), tin dioxide (SnO₂), and fluorine-dope tin oxide (FTO).

3. The apparatus of claim 1, wherein the triboelectric material is above and in electrical contact with the electrode portion of thin film layer.

4. The apparatus of claim 1, wherein a portion of the triboelectric material and a corresponding portion of the electrode portion form a triboelectric-based sensor, and wherein a portion of the resistive portion comprises a serpentine shape extending laterally from the triboelectric-based sensor to form a thin film resistor.

5. The apparatus of claim 4, further comprising a flexible substrate, wherein the triboelectric-based sensor and the thin film resistor are formed on the flexible substrate.

6. The apparatus of claim 5, wherein the flexible substrate is transparent. The apparatus of claim 1, wherein the electrode portion and the resistive portion comprise the same material, and wherein the resistive portion of the thin film material comprises a higher oxygen content than the electrode portion.

8. The apparatus of claim 1, further comprising a protective film around the resistive portion of the thin film layer, wherein the protective film comprises the triboelectric material.

9. The apparatus of claim 1, wherein the triboelectric material comprises at least one of polyvinylidene fluoride (PVDF), a copolymer of PVDF, polydimethylsiloxane (PDMS), poly(methylmethacrylate) (PMMA), polytetrafluoroethylene, polymer foam, poly(methylmethacrylate)-co-poly(1H-1H-perfluorooctylmethacrylate), poly-xylylene polymer, a fluorinated polymer, and an electronegative polymer.

10. A method for manufacturing a triboelectric sensor device, comprising:
forming a first thin film layer comprising a transparent conducting oxide and comprising an electrode portion and a resistive portion, wherein the resistive portion has a higher resistivity than the electrode portion; and
forming a triboelectric thin film layer above the first thin film layer and in contact with the electrode portion of the first thin film layer,
wherein at least a portion of the triboelectric thin film layer is coupled to at least a portion of the electrode portion to form a triboelectric-based sensor, and
wherein the triboelectric-based sensor is coupled to at least a portion of the resistive portion that forms a thin film resistor.

11. The method of claim 10, wherein the step of forming the first thin film layer comprises:
forming a conductive thin film material in a first layer on a substrate, wherein the conductive thin film material forms the electrode portion; and
forming a resistive thin film material having a higher resistance than the conductive thin film, wherein the resistive thin film is in the first layer and forms the resistive portion.

12. The method of claim 10, wherein the step of forming the conductive thin film material comprises forming the conductive thin film material by a lift-off process, the lift-off process comprising:
depositing a photoresist layer;
patterning the photoresist layer with a pattern corresponding to the electrode portion;
depositing the conductive thin film material; and
removing the photoresist layer to lift off portions of the conductive thin film material not in the electrode portion.

13. The method of claim 10, wherein the step of forming the resistive thin film material comprises incorporating oxygen into the resistive thin film material to obtain the higher resistance.

14. The method of claim 13, wherein the step of forming the resistive thin film material comprises depositing the same material as the conductive thin film material before incorporating oxygen into the resistive thin film material.

15. The method of claim 10, wherein the step of forming the first thin film layer comprises forming at least a portion of the electrode portion or the resistive portion from at least one of tin-doped indium oxide (ITO), aluminum-doped zinc oxide (AZO), gallium-doped zinc oxide (GZO), tin dioxide (SnO₂), and fluorine-dope tin oxide (FTO).

16. The method of claim 10, wherein the step of forming the triboelectric thin film layer comprises forming at least one of PVDF, a copolymer of PVDF, PDMS, PMMA, tetrafluoroethylene, polymer foam, poly(methylmethacrylate)-co-poly(1H-1H-perfluorooctyl methacrylate), poly-xylylene polymer, a fluorinated polymer, and an electronegative polymer.

17. An electronic device, comprising:
a triboelectric-based sensor; and
an integrated circuit coupled to the triboelectric-based sensor and configured to read-out a user input to the triboelectric-based sensor, wherein the triboelectric-based sensor comprises:
a triboelectric material; and
a thin film layer coupled to the triboelectric material, wherein the thin film layer comprises an electrode portion coupled to the triboelectric material and a resistive portion coupled to the electrode portion, wherein the resistive portion has a higher resistivity than the electrode portion, and wherein the thin film layer comprises a transparent conducting oxide.

18. The electronic device of claim 17, further comprising a flexible substrate, wherein the triboelectric-based sensor is formed on the flexible substrate, wherein the flexible substrate is transparent.

19. The electronic device of claim 17, wherein the resistive portion of the thin film material comprises a higher oxygen content than the electrode portion.

20. The electronic device of claim 17, wherein a portion of the resistive portion comprises a serpentine shape extending laterally from the triboelectric-based sensor to form a thin film resistor.
